(19) United States
(12) Patent Application Publication
(10) Pub. No.: US 2010/0231330 A1
(43) Pub. Date: Sep. 16, 2010

(54) Component Working with Guided Bulk Acoustic Waves

(76) Inventors: Werner Ruile, Muenchen (DE); Ulrike Roesler, Hebertshausen (DE); Markus Hauser, Feldafing (DE)

Correspondence Address: SLATER & MATSIL, L.L.P., 17950 PRESTON RD, SUITE 1000, DALLAS, TX, 75252-5793, US

(21) Appl. No.: 12/558,778

(22) Filed: Sep. 14, 2009

Related U.S. Application Data
(63) Continuation of application No. PCT/EP2008/052955, filed on Mar. 12, 2008.

(30) Foreign Application Priority Data
Mar. 14, 2007 (DE) 10 2007 012 383.5

(51) Int. Cl. H03H 9/02

(52) U.S. Cl. 333/193

(57) ABSTRACT

A component working with guided bulk acoustic waves is disclosed with at least one substrate and a layer system that is connected to this substrate and suitable for wave propagation. The layer system includes a metallization layer, a first dielectric layer, and a second dielectric layer. The velocity of the acoustic wave is greater in the second dielectric layer than in the first dielectric layer. At least one of the dielectric layers contains TeO₂.

This application is a continuation of co-pending International Application No. PCT/EP2008/052955, filed Mar. 12, 2008, which designated the United States and was not published in English, and which claims priority to German Application No. 10 2007 012 383.5 filed Mar. 14, 2007, both of which applications are incorporated herein by reference.

### BACKGROUND

A component working with GBAW, or Guided Bulk Acoustic Waves, will be disclosed. The guided bulk acoustic waves are also called “boundary acoustic waves.” Components working with GBAW are known from EP 1538748 A2 (U.S. equivalent U.S. Pat. No. 7,224,101), US 2006/0175928 A1, U.S. Pat. No. 6,046,656, and US 2007/0018536 A1.

### SUMMARY

A component working with GBAW of the frequency with a small temperature response is disclosed.

A component working with guided acoustic waves is disclosed with at least one substrate and one layer system that is arranged on this substrate and suitable for wave propagation. The layer system comprises a metallization layer, a first dielectric layer, and a second dielectric layer. The velocity of the acoustic wave is greater in the second dielectric layer than in the first dielectric layer. One of the dielectric layers contains TeO₂. The other dielectric layer advantageously contains SiO₂.

The piezoelectric substrate or the substrate comprising a piezoelectric layer, on which substrate the metallization layer is generated, typically features a negative temperature response of the stiffness coefficient. TeO₂ features the opposite, i.e., positive temperature response of the stiffness coefficient. Therefore, as the material for the first dielectric layer that borders this substrate in a few regions, TeO₂ has advantages with respect to compensating the temperature response of the substrate for achieving an overall component with a low temperature response of the frequency.

The metallization layer is structured for forming electrode structures of electroacoustic converters, reflectors, track conductors, and contact surfaces that can be advantageously contacted from the outside.

The boundary surface between the first and second dielectric layers is advantageously uneven. However, the boundary surface between the first and second dielectric layers could also be planar and, in particular examples, planarized.

The unevenness of the surface of the first dielectric layer is produced, in particular, because this layer is deposited onto the structured metallization layer.

Below, advantageous constructions of the component according to the first and second embodiment are described. The first and second embodiment can be combined with each other.

The metallization layer is arranged on the substrate. The first dielectric layer is arranged between the metallization layer and the second dielectric layer. The first dielectric layer advantageously directly borders the metallization layer. The first dielectric layer covers the structures of the metallization layer and is flush with the substrate in the areas free from these structures.

In one embodiment, the second dielectric layer is arranged between the first dielectric layer and a cover layer. The second dielectric layer has at least one electrically insulating layer. The cover layer advantageously contains a material, such as, e.g., resin, photoresist, or another organic material that is suitable for damping acoustic waves.

A relatively large difference in velocity between the two dielectric layers is advantageous for wave propagation or concentration of the energy of the acoustic wave onto the narrowest space possible (with respect to a vertical direction). The difference in the acoustic velocity between the first and the second dielectric layer advantageously equals at least the factor of 1.5.

A relatively small difference in acoustic impedance between the two dielectric layers is advantageous because, in this case, it does not affect the quality of the boundary surface formed between these layers in terms of achieving low tolerances of the component. For this reason, after the frequency trimming in which, among other things, the thickness of the first dielectric layer is changed to reach the specified frequency of the component, among other things, an expensive planarization step for the planarization of the surface of this layer can be eliminated before the deposition of the second dielectric layer. The difference in the acoustic impedance between the first and the second dielectric layer advantageously equals a maximum of 50%.

A relatively large difference in acoustic impedance between the metallization layer and the dielectric layer bordering it is advantageous for achieving a relatively large acoustic reflection at the edges of the electrode structures.

The first dielectric layer advantageously has a thickness that is not sufficient for the complete decay of the acoustic wave in the vertical direction, so that a portion of the energy of the wave is present in the second dielectric layer. The thickness of the first dielectric layer advantageously equals between 0.2λ and 1.0λ, wherein λ is the wavelength at the operating frequency of the component.

The second dielectric layer has a thickness that is sufficient for an advantageously complete decay of the acoustic wave in the vertical direction. The thickness of the second dielectric layer advantageously equals at least λ, in one advantageous embodiment at least 2λ. The total thickness of the substrate is selected so that the wave can decay completely within the substrate. The total thickness of the substrate equals, e.g., at least 5λ.

In one advantageous embodiment, the first dielectric layer contains TeO₂, and the second dielectric layer contains SiO₂ that has a higher acoustic velocity than TeO₂.

The substrate can be, e.g., a lithium niobate single crystal. The crystal section LiNbO₃ φ YX where φ=5°-25°, e.g., φ=15°, is especially advantageous for reaching a large electromechanical coupling. The large coupling has advantages with respect to a large bandwidth of the component.

The substrate can alternatively have at least one layer made from lithium niobate. Alternatively, lithium tantalate or another piezoelectric material could be used.

In one embodiment, the acoustic wave excited in the component is a horizontally polarized shear wave. In another embodiment, it is also possible to use other acoustic modes.

At least one of the dielectric layers advantageously has a temperature response opposite that of the substrate for the stiffness coefficient that is decisive for the wave. In one embodiment, this is the first dielectric layer and, in another embodiment, this is the second dielectric layer. In another embodiment, this applies to both dielectric layers.

In one embodiment, it is valid for at least one of the dielectric layers, advantageously for both dielectric layers, that the stiffness of the corresponding material increases with increasing temperature T, wherein the stiffness of the substrate decreases with increasing temperature. This means that dc/dT>0, where c is the stiffness index that is decisive for the wave, e.g., c-c₁₁ or c₄₄. Advantageously, because a horizontally polarized shear wave for which c₄₄ is decisive is to be excited, advantageously it is valid that: dc₄₄/dT>0. For a component working with longitudinal waves, it is valid accordingly that: dc₁₁/dT>0.

In another embodiment, it is valid for at least one of the dielectric layers, advantageously for both dielectric layers, that the stiffness of the corresponding material decreases with increasing temperature T, wherein the stiffness of the substrate increases with increasing temperature. This means that dc/dT>0, i.e., according to the wave mode, dc₄₄/dT>0 or dc₁₁/dT>0.

Through the compensation of the temperature response of the elastic properties of the substrate and the layer system, it is possible to produce a component working with GBAW of the operating frequency with a very small temperature response.

The metallization layer advantageously has at least one electrically conductive layer whose material features a higher acoustic impedance than that of aluminum. The following materials come into consideration: Cu, Ti, Cr, Mo, W, Mg, Au, Pt, Ta, Ni, as well as other conductive materials with a high acoustic impedance. The acoustic impedance of these materials is significantly higher than that of the first dielectric layer. Thus, an especially high acoustic reflection can be achieved at the edges of the electrode structures.

In one embodiment, the metallization layer has at least one electrically conductive layer that contains aluminum. In addition to at least one relatively lightweight Al layer whose acoustic impedance is relatively small and comparable with that of the bordering dielectric layer, advantageously at least one relatively heavy metal layer made from the previously mentioned materials is used.

The substrate has at least one piezoelectric layer on which the metallization layer is arranged. The metallization layer advantageously borders the piezoelectric layer directly. It is advantageous if the acoustic velocity in the piezoelectric layer is greater than that in the first dielectric layer that is flush with the piezoelectric layer in a few areas.

In one embodiment, the piezoelectric layer is arranged on a non-piezoelectric layer that contains, e.g., LTCC or HTCC ceramic, silicon, glass, Al₂O₃, or an organic plastic, such as, e.g., FR4. In this case, it is possible to form the piezoelectric layer with a very small thickness and to use the non-piezoelectric layer of the substrate as a carrier substrate and/or growth substrate for the piezoelectric layer. The thickness of the piezoelectric layer is advantageously selected so that the acoustic wave essentially decays completely within this layer.

The acoustic velocity in the non-piezoelectric layer is advantageously greater than in the piezoelectric layer, so that the wave there decays as quickly as possible. This is valid, especially when a portion of the energy is present in the non-piezoelectric layer. It is advantageous if the difference in velocity between the piezoelectric layer and the non-piezoelectric layer is relatively large and equals, e.g., at least the factor of 1.5.

### BRIEF DESCRIPTION OF THE DRAWINGS

Below, the disclosed component and its advantageous constructions will be explained with reference to schematic figures that are not to scale.

FIG. 1, shows in cross section, a GBAW component;

FIG. 2, shows in cross section, another GBAW component; and

FIG. 3, shows a view of a resonator working with GBAW.

The following list of reference symbols may be used in conjunction with the drawings:
1 Substrate
11 Non-piezoelectric layer of the substrate 1
12 Piezoelectric layer
2 Cover layer
3 Layer system
31 First dielectric layer
32 Second dielectric layer
33 Metallization layer
331 First conductive layer
332 Second conductive layer
41 Converter
42, 43 Reflectors

### DETAILED DESCRIPTION OF ILLUSTRATIVE EMBODIMENTS

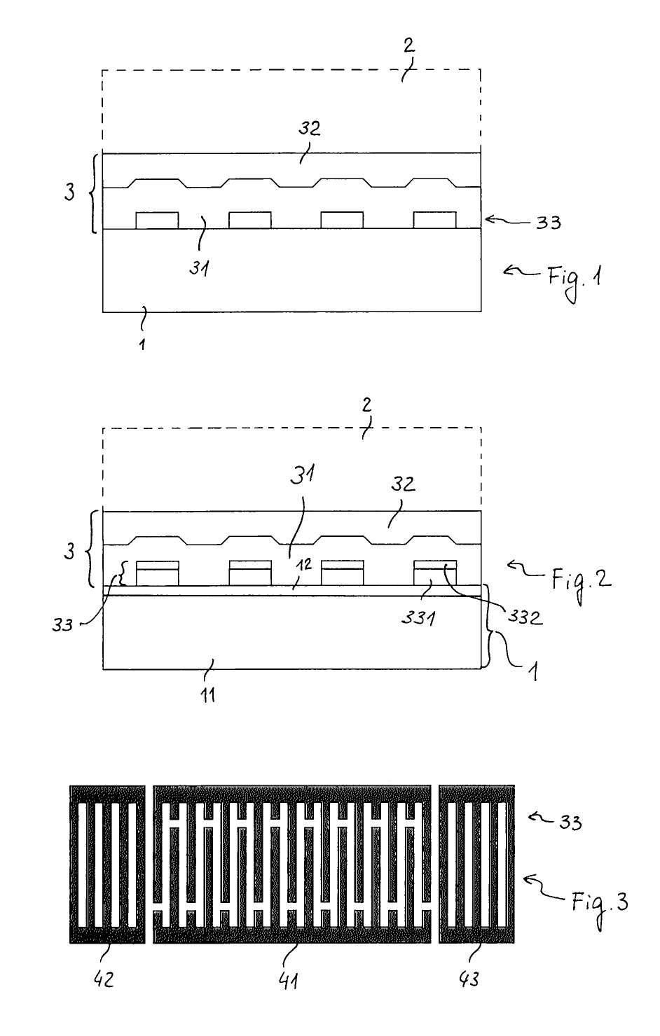

In FIG. 1, a component working with guided bulk acoustic waves is shown with a substrate 1 and a layer system 3 arranged on this substrate. The layer system 3 comprises a metallization layer 33, a first dielectric layer 31, and a second dielectric layer 32.

In one embodiment, a cover layer 2 made from an acoustically damping material, i.e., a material with a low stiffness, can be connected rigidly to the layer system 3. The second dielectric layer 32 is arranged between the first dielectric layer 31 and the cover layer 2. However, the second dielectric layer 32 can also represent a terminal layer with an exposed surface.

A metallization layer 33 structured for forming converters 41, reflectors 42, 43, track conductors, and electrical contact surfaces is generated on the substrate 1 (see FIG. 1). The track conductors here connect the converters to each other and to the contact surfaces (not shown in the figures). The converter 41 and the reflectors 42, 43 have strip-shaped electrode structures.

Then the first dielectric layer 31, e.g., made from TeO₂, is deposited on the substrate 1 with the structured metallization layer 33 through vapor deposition or another deposition method. This layer covers the electrode structures and is flush with the surface of the substrate 1. The surface of this layer is not smooth because the electrode structures “press through.” The frequency position of the component is evaluated, and the first dielectric layer 31 is either made thinner for increasing the frequency position or made thicker for decreasing the operating frequency. The thinning can be performed in an etching method, and the thickening can be performed through sputtering or another advantageously economical method. The thinning can also be performed through mechanical removal of the material. The tuning of the frequency position of the component is called trimming.

After the trimming, the second dielectric layer 32 advantageously made from silicon dioxide is generated on the layer 31, e.g., by means of vapor deposition or sputtering.

The electrical contacting of the electroacoustically active component structures 41, 42, 43 formed in the metallization layer 33 can be performed from the side of the substrate and/or from the other side. In this way, the substrate 1 and optionally the cover layer 2 and optionally the dielectric layers 31, 32 are contacted through.

In the embodiment presented in FIG. 2, the metallization layer 33 has a first conductive layer 331 and a second conductive layer 332 arranged on this first layer. In one embodiment, the first conductive layer 331 contains metallic aluminum and the second conductive layer 332 contains a metal with a higher acoustic impedance. In another embodiment, the first conductive layer 331 contains a metal with a higher acoustic impedance and the second conductive layer 332 contains metallic aluminum.

In the embodiment according to FIG. 1, the substrate 1 has piezoelectric properties. In the embodiment according to FIG. 2, a piezoelectric layer 12 is generated on a non-piezoelectric layer 11 for forming the substrate 1. As noted above, the various embodiments can be combined with each other.

In FIG. 3, a resonator working with GBAW is shown with a converter 41 and two reflectors 42, 43. The converter 41 is arranged between the reflectors 42, 43. The converter 41 has strip-shaped electrode structures that are connected in the shown embodiment alternately to two different bus bars. The acoustic wave is excited between two electrode structures of different polarity.

The specified GBAW component is neither limited to the embodiments nor to the specified materials shown in the figures. The mentioned materials could be replaced by other materials with properties that are similar in terms of acoustic impedance and acoustic velocity.

What is claimed is:

1. A component working with guided bulk acoustic waves, the component comprising:
a substrate; and
a layer system arranged over the substrate, the layer being suitable for wave propagation;
wherein the layer system comprises a metallization layer, a first dielectric layer, and a second dielectric layer,
wherein a velocity of an acoustic wave in the second dielectric layer is greater than in the first dielectric layer, and
wherein the first and/or the second dielectric layer comprises TeO₂.

2. The component according to claim 1, wherein the first dielectric layer comprises TeO₂.

3. The component according to claim 1, wherein the second dielectric layer comprises TeO₂.

4. The component according to claim 2, wherein the second dielectric layer comprises SiO₂.

5. The component according to claim 3, wherein the first dielectric layer comprises SiO₂.

6. The component according to claim 1, wherein the metallization layer is arranged on the substrate and wherein the first dielectric layer is arranged between the metallization layer and the second dielectric layer.

7. The component according to claim 1, wherein the velocity of an acoustic wave in the second dielectric layer is at least 1.5 times greater than in the first dielectric layer.

8. The component according to claim 1, wherein the difference in acoustic impedance between the first and the second dielectric layers equals a maximum of 50%.

9. The component according to claim 1, wherein a temperature response of stiffness of the first and second dielectric layers is opposite that of the substrate.

10. The component according to claim 9,
wherein, for the first and the second dielectric layers, it is valid that the stiffness of the corresponding material increases with increasing temperature, and
wherein the stiffness of the substrate decreases with increasing temperature.

11. The component according to claim 9,
wherein, for the first and the second dielectric layers, it is valid that the stiffness of the corresponding material decreases with increasing temperature, and
wherein the stiffness of the substrate increases with increasing temperature.

12. The component according to claim 1, wherein the first dielectric layer has a thickness between 0.2λ and λ, where λ is the wavelength at an operating frequency of the component.

13. The component according to claim 1, wherein the second dielectric layer has a thickness of at least λ, where λ is the wavelength at an operating frequency of the component.

14. The component according to claim 1, wherein a boundary surface between the first and second dielectric layers is uneven.

15. The component according to claim 1,
wherein the first dielectric layer borders the metallization layer, and
wherein the metallization layer has at least one electrically conductive layer with a material that has an acoustic impedance that is at least twice as large as an acoustic impedance of the first dielectric layer.

16. The component according to claim 1, wherein the metallization layer has at least one electrically conductive layer with a material that has a higher acoustic impedance than an acoustic impedance of aluminum.

17. The component according to claim 1, wherein the metallization layer has at least one electrically conductive layer that comprises aluminum.

18. The component according to claim 1, wherein the substrate has at least one piezoelectric layer on which the metallization layer is arranged.

19. The component according to claim 18, wherein the piezoelectric layer is arranged on a non-piezoelectric layer.
